(19) United States
(12) Patent Application Publication
(10) Pub. No.: US 2019/0250114 A1
(43) Pub. Date: Aug. 15, 2019

(54) Integrated Graphene-CMOS Device for Detecting Chemical and Biological Agents and Method for Fabricating Same

(71) Applicant: The United States of America as represented by the Secretary of the Navy, San Diego, CA (US)

(72) Inventors: Nackieb M. Kamin, Kapolei, HI (US); Marcio Calixto de Andrade, San Diego, CA (US); David Garmire, Honolulu, HI (US); Richard Christopher Ordonez, Mililani, HI (US)

(21) Appl. No.: 15/894,607

(22) Filed: Feb. 12, 2018

(51) Int. Cl. G01N 27/12; H01L 29/16; H01L 21/02; H01L 21/8234

(52) U.S. Cl. CPC G01N 27/125; H01L 29/1606; G01N 27/122; H01L 21/823475; H01L 21/02527

(57) ABSTRACT

A detection device detects the presence of a chemical or biological agent in an environment. The detection device includes a metal layer including a plurality of electrodes. The device further includes a graphene layer covering a surface of the metal layer of electrodes and a detection layer connected to the electrodes. Contact of a biological or chemical agent with a surface of the graphene layer causes a change in resistance of the graphene layer. The detection layer includes detection circuitry configured to detect the change in resistance as a function of a measured change in a current or voltage between adjacent electrodes.

### FEDERALLY-SPONSORED RESEARCH AND DEVELOPMENT

The Integrated Graphene-CMOS Device for Detecting Chemical and Biological Agents and Method for Fabricating Same is assigned to the United States Government and is available for licensing for commercial purposes. Licensing and technical inquiries may be directed to Office of Research and Technical Applications, Space and Naval Warfare Systems Center, Pacific, Code 72120, San Diego, Calif., 92152; telephone (619) 553-5118; email: ssc pac t2@navy.mil, referencing NC102927.

### BACKGROUND

Detection and characterization of various chemical and biological agents (bioagents) in low concentrations are becoming increasingly important in environmental monitoring, disaster relief and counter-narcotics.

Traditional detection techniques for detection of bioagents are culture-based. More recently developed methods include antibody-based techniques, Polymerase Chain Reaction (PCR), time-of-flight mass spectrometry, flow cytometry, etc.

While these techniques are somewhat effective, they are often used after the fact, e.g., to confirm a clinician's suspected diagnosis. Further, these techniques often require expensive and immobile equipment, requiring laboratory conditions for successful analysis. Also, these techniques typically take up to twenty-four (24) hours and thus lack the required response time, specificity and selectivity needed in the event of, for example, a natural disaster or a chemical/bioagent attack.

In view of the above, it would be desirable to provide a detection device that is capable of quickly and accurately detecting the presence and concentration of chemicals and/or bioagents in an environment.

### SUMMARY

According to an illustrative embodiment, a detection device is provided for detecting a chemical or biological agent. The detection device includes a metal layer including a plurality of electrodes. The device further includes a graphene layer covering a surface of the metal layer of electrodes and a detection layer connected to the electrodes. Contact of a biological or chemical agent with a surface of the graphene layer causes a change in resistance of the graphene layer. The detection layer includes detection circuitry configured to detect the change in resistance as a function of a measured change in a current or voltage between adjacent electrodes in the plurality of electrodes.

These, as well as other objects, features and benefits will now become clear from a review of the following detailed description, the illustrative embodiments, and the accompanying drawings.

### BRIEF DESCRIPTION OF THE DRAWINGS

The novel features described herein will be best understood from the accompanying drawings, taken in conjunction with the accompanying description, in which similarly-referenced characters refer to similarly-referenced parts, and in which:

FIG. 1 depicts a cross-sectional view of a detection device according to illustrative embodiments;

FIG. 2 depicts a three-dimensional view of a detection device including a graphene layer according to an illustrative embodiment;

FIG. 3A depicts a detailed three-dimensional view of a detection device including detection circuitry according to illustrative embodiments;

FIG. 3B depicts a detailed cross-sectional view of a portion of a detection device including detection circuitry according to an illustrative embodiment;

FIG. 3C illustrates an example of detection circuitry included in a detection device according to an illustrative embodiment;

FIG. 4A illustrates details of circuitry including a current source according to an illustrative embodiment;

FIG. 4B illustrates details of circuitry including a voltage source according to an illustrative embodiment;

FIG. 5A is a plot showing a change in resistance of graphene upon contact or bonding with a biological or chemical agent;

FIG. 5B is a plot of a normalized resistance of graphene over time responsive to contact or bonding with a biological or chemical agent according to an illustrative embodiment;

FIGS. 6A, 6B, and 6C illustrate stages in a process for fabricating a graphene covered detection device according to an illustrative embodiment;

FIG. 7A is a flow chart illustrating the steps involved in a process for fabricating a functionalized graphene covered detection device according to an illustrative embodiment;

FIG. 7B is a flow chart illustrating the steps involved in a process for fabricating a functionalized graphene covered detection device according to another illustrative embodiment; and

FIG. 8 is a flow chart illustrating the steps involved in a process for fabricating a metal layer and a detection layer according to an illustrative embodiment.

### DETAILED DESCRIPTION OF THE EMBODIMENTS

According to illustrative embodiments, a detection device for detecting a chemical or biological agent includes a graphene layer covering an array of electrodes with underlying detection circuitry. The detection device quickly and accurately detects the presence and concentration of biological or chemical agents in a liquid or gaseous environment.

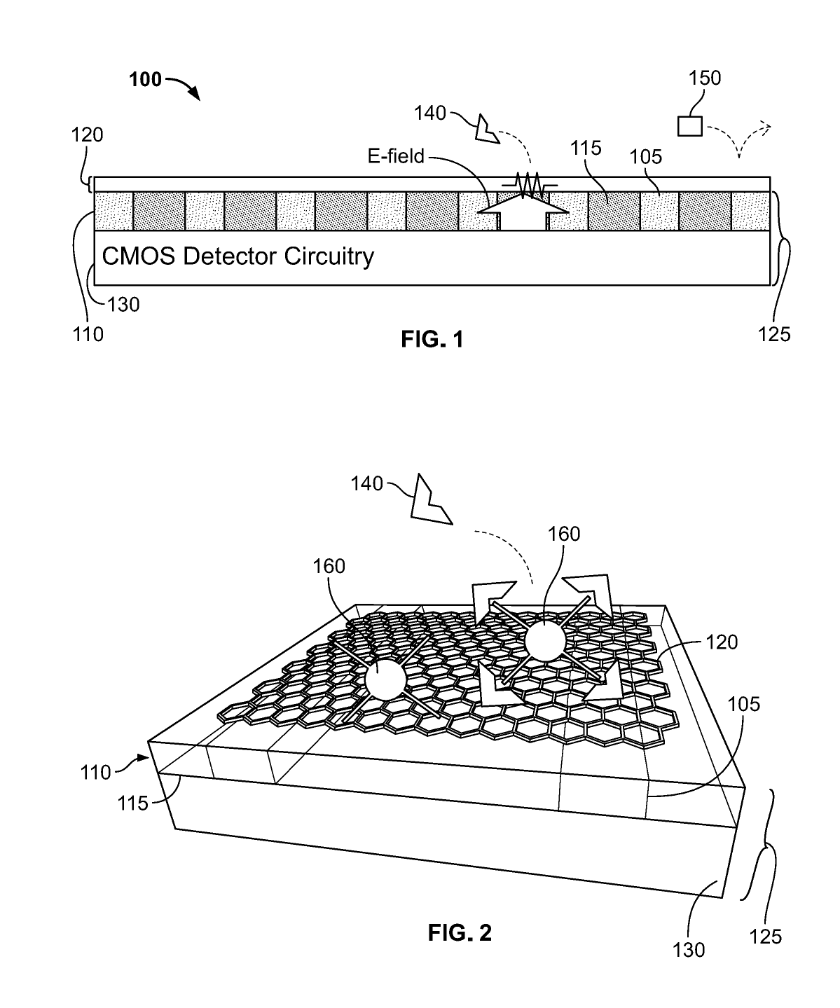

FIG. 1 depicts a cross sectional view of a detection device according to illustrative embodiments. As shown in FIG. 1, the device 100 includes an electronic platform, such as a complementary metal oxide semiconductor (CMOS) metal layer 110. The CMOS metal layer 110 includes CMOS electrodes 105 separated by insulating material 115. The insulating material 115 may include, for example, dielectric material. The CMOS metal layer 110 is covered with a graphene layer 120. The CMOS metal layer 110 is supported by a CMOS detection layer 130 including bulk material and detection circuitry. The CMOS metal layer 110 and the CMOS detection layer make up a CMOS layer 125.

The graphene layer 120 has a variable resistance that reacts to external stimuli such as a chemical, electrochemical, electrostatic, or electrical field caused by a chemical agent 140 or biological agent 140 contacting or bonding with the graphene layer 120. The change in resistance of the graphene layer 120 between adjacent electrodes 105 alters the current or voltage at the electrodes 105. The difference in current or voltage can be detected by detection circuitry in the CMOS detection layer 130, as described in further detail below.

To aid in understanding how a change in the resistance of the graphene layer 120 causes a change in voltage or current at the electrodes 105 that is detectable by the detection circuitry in the CMOS detection layer 130, a brief explanation of the properties of graphene is provided. Graphene has extremely high electron mobility approaching ballistic speeds greater than 100,000 cm²N-s at room temperature. Furthermore, graphene is capable of generating conduction electrons from minute localized electric fields due to its zero bandgap nature. A small local electric field from an ion (charged molecule) in a gaseous or liquid environment excites electrons into the conduction band, creating electron-hole pairs which can subsequently be sensed by electronic amplification. Small localized charging from contacting/bonding agents similarly affects the electronic properties of the graphene. Similarly, such localized charging may cause an electronic change in current. Such changes in current or voltage are detectable by neighboring circuitry and makes graphene ideal for sensitive applications where electronic changes are small. Because graphene has a thickness of one atom, the detection circuitry can be included in the CMOS detection layer 130, on the opposite side of the graphene layer 120 from the CMOS metal layer 110.

In the example shown in FIG. 1, a biological or chemical agent 140 that contacts or bonds with the graphene layer 120 releases a charge, generating a local electric field between the bonding agent and charged surface of the graphene layer 120. This electric field manipulates the Fermi energy level of graphene layer 120, making the graphene more conductive and thereby effectively lowering the resistance of the graphene layer 120.

As another example, a highly energetic contact/bonding agent will cause charges to be released from the graphene layer 120. The free charges would contribute to the current change between adjacent electrodes 105.

In another example, a charged contact/bonding agent creates an electrochemical reaction that alters the conductivity (and hence the resistance) of the graphene layer 120.

According to one embodiment, the graphene layer 120 may be non-functionalized such that it reacts to any charged biological or chemical agent coming close to or contacting the surface of the graphene layer. As the charged agent 140 comes close to or contacts the surface of the graphene layer 120, this will create conduction between the electrodes 105, causing a change in resistance of the graphene layer 120 between the electrodes 105.

According to another embodiment, the graphene layer 120 is functionalized such that it reacts only to a particular biological or chemical agent 140. As those skilled in the art will appreciate, functionalizing of the graphene layer includes applying, for example, receptors or chemical compounds to the graphene such that particular bioagents or chemical agents that contact the functionalized graphene layer will bond with graphene layer 120. This bonding alters conduction between the electrodes 105, causing a change in resistance of the graphene layer 120 between the electrodes 105.

According to this embodiment, the graphene layer 120 may be functionalized such that it attracts a particular bioagent or chemical agent 140, thereby making it possible to provide specialized detection for a particular bioagent or chemical agent 140. Molecules of bioagents and chemical agents 140 for which the graphene 120 is not functionalized to bond to, such as the molecule 150 shown in FIG. 1, will be repelled from the functionalized graphene layer 120.

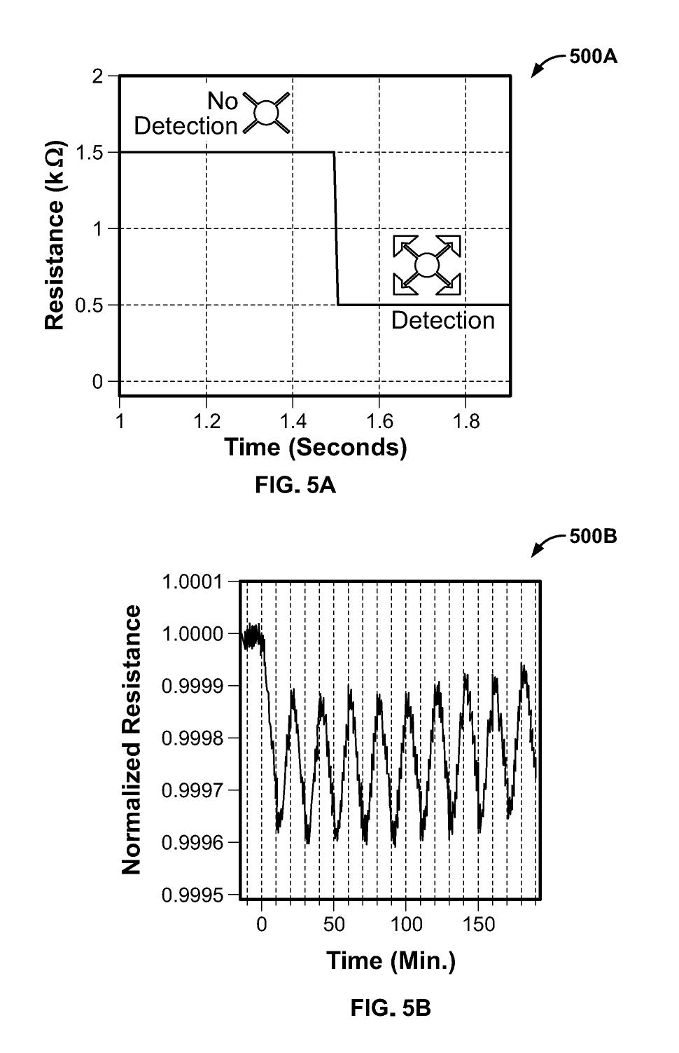

The change in resistance of the graphene layer 120 caused either by contact or bonding of a charged molecule of a biological or chemical agent 140 causes a change in resistance that is detectable as a function of a measured change in voltage or current by the underlying CMOS detection layer 130. For example, with a known current at each electrode 105, the resistance may be obtained based on the voltage difference between the electrodes 105. With a known voltage at each electrode 105, the resistance may be obtained based on the difference in current at each electrode 105. The change in resistance over time may be displayed, for example, on a monitor connected to the CMOS detector layer 130. Based on the change in resistance, the particular agent 140 that contacts or bonds with the graphene 120 can be determined. This is explained in more detail below with reference to FIGS. 5A and 5B.

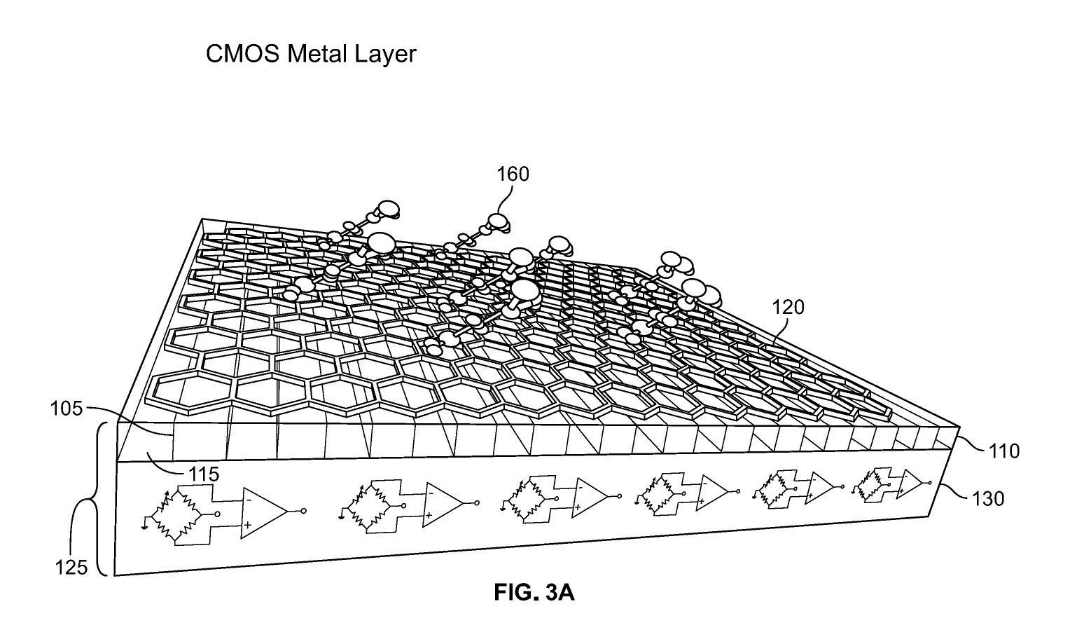

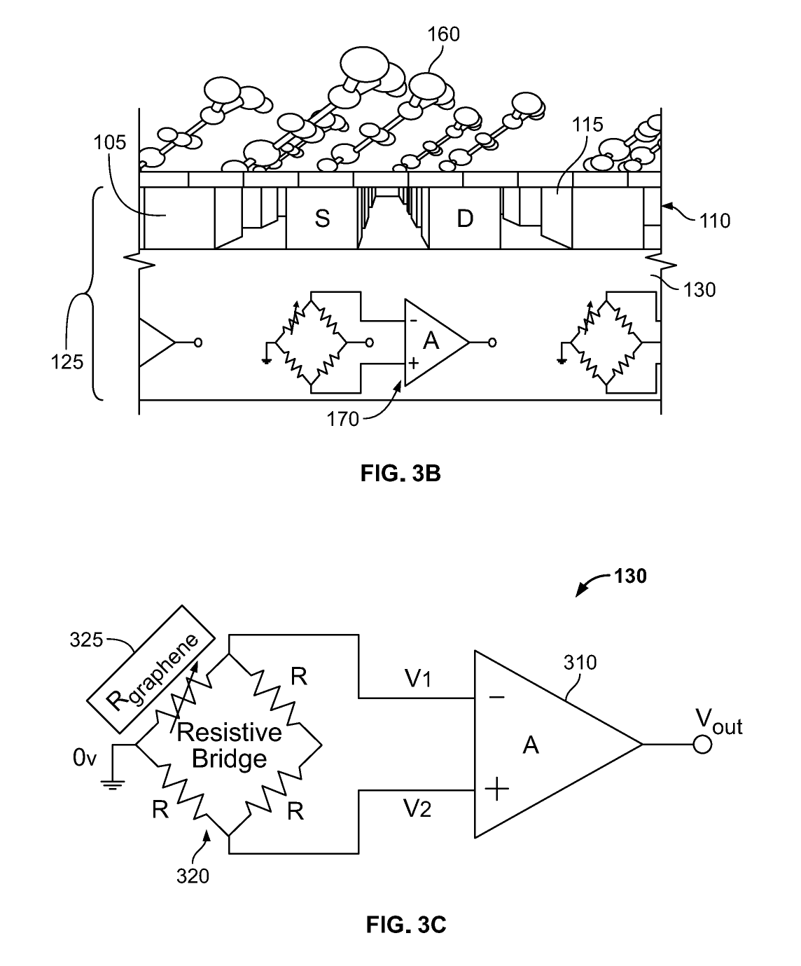

FIG. 2 depicts a three dimensional view of a detection device including a functionalized graphene layer 120 according to an illustrative embodiment. As shown in FIG. 2, the graphene layer 120 includes a two dimensional honeycomb lattice of carbon atoms. The carbon atoms are held together by strong Van der Waals forces. A change in resistance occurs as a biological agent or a chemical agent 140 comes into contact with or bonds with a molecule 160 used to functionalize the graphene layer 120. While FIG. 2 only depicts two electrodes 105 for ease of explanation, the detection device may include any number of electrodes 105. Further, the electrodes 105 may be arranged in an array, as shown in FIG. 3A and described below.

FIG. 3A illustrates details of a graphene covered detection device according to illustrative embodiments. The spacing between the CMOS electrodes 105 may be on the nanometer scale. Also, as shown in FIG. 3A, the CMOS electrodes 105 may be arranged in an array, covered with the graphene layer 120. The spacing and arrangement of the CMOS electrodes 105 within the array allow for quick and accurate detection of not only the presence of bioagents 140 and chemicals in a liquid or gaseous environment, but also the spatial concentration of such agents in the environment. This is described in more detail below.

According to an illustrative embodiment, one electrode of a pair of adjacent electrodes may be considered a source, and the other electrode of the pair may be considered a drain. Both the “source” electrode and the “drain” electrode are in contact with the graphene layer 120. The “source” and “drain” electrodes may, in turn, be connected to the CMOS detection layer 130. This may be understood with reference to FIG. 3B which illustrates a simplified device schematic showing a portion of the device shown in FIG. 3A. As shown in FIG. 3B, adjacent “source” and “drain” electrodes (labeled “S” and “D”, respectively) act as sense rails, providing inputs to CMOS detection layer 130. In the example illustrated in FIG. 3B, the CMOS detection circuitry in the detection layer 130 includes a Wheatstone bridge with an instrumentation/differential amplifier circuit 170. It should be appreciated that this circuitry is shown by way of example, and that that the detection circuitry in the CMOS detection layer 130 may include any other suitable circuitry.

Referring to both FIGS. 3A and 3B, gating is achieved by contact or bonding of biological agent or chemical agent with the graphene layer 120. As shown in FIGS. 3A and 3B, a charged molecule 160 is used to functionalize the graphene layer 120 such that a particular biological or chemical agent will bond to the graphene layer 120 upon contact. The contact/bonding allows conduction between the “source” electrode and the “drain” electrode, thus changing the conductivity/resistance of the graphene layer 120. This change in resistance can be measured by the circuitry in the CMOS detection layer 130 as a difference in voltage or current between the “source” and “drain” electrodes, as explained in further detail below. The voltage or current differences are measured between adjacent electrodes included in the array of electrodes shown in FIG. 3A. By measuring the voltage or current differences over the array of electrodes, the contact/bonding of biological or chemical agents at various portions on the graphene layer 120 covering the array can be quickly detected, such that the spatial concentration of such agents in the environment in which the detection device is used can be easily determined.

FIG. 3C illustrates an example of CMOS detection circuitry included in a detection device according to an illustrative embodiment. Referring to FIG. 3C, in this example, the detection circuitry in the CMOS detection layer 130 includes a resistive bridge 320. The portion of the graphene layer 120 between adjacent electrodes serves as a branch 325 of the resistive bridge 320. The branch 325 has a variable resistance R_{graphene}, while the other branches of the resistive bridge each have a fixed resistance R. The outputs of the resistive bridge 320 represent interconnections of the adjacent electrodes to the graphene layer 120 and the CMOS detection layer 130. These outputs are fed as inputs into an operational amplifier 310. Thus, the adjacent electrodes act as sense rails. Any change in the conductivity of graphene layer 120 due to contact or bonding of a biological or chemical agent will be sensed by the electrodes and provided as inputs to the operational amplifier 310.

In the embodiment shown in FIG. 3C, the voltages V1 and V2 represent inputs from adjacent “source” and “drain” electrodes, respectively. As can be seen from FIG. 3C, the inputs of the operational amplifier 310 are not referenced to a supply ground but rather are “floating”. This allows the operation amplifier 310 to measure the difference between the two inputs and suppress any voltage common to the two inputs (which is typically noise). The output Vₒᵤₜ is the difference between the two inputs. Using the circuitry shown in FIG. 3C, very minute changes in the voltage (or current) at the adjacent electrodes can be measured.

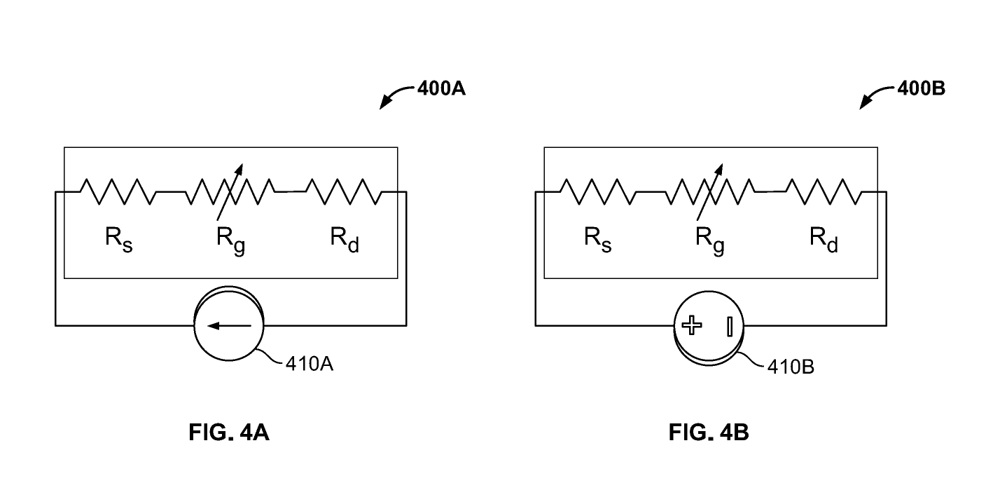

According to illustrative embodiments, the graphene layer 120 acts as a variable resistor that changes resistance/impedance upon bonding or contact with a chemical or biological agent. Circuit models showing the graphene layer 120 as a variable resistor are shown in FIGS. 4A and 4B.

FIG. 4A illustrates details of circuitry 400A including a current source according to an illustrative embodiment. The current source 410 may be implemented with, for example, a simple current mirror, Wilson current mirrors, a modified/regulate cascade current mirror, an adjustable current mirror, or a commercial, off-the-shelf current source.

As shown in FIG. 4A, the current source 410A supplies current to a source electrode, represented as a resistor Rₛ having a fixed resistance. The current then passes through the portion of the graphene layer between the “source” electrode and the “drain” electrode, the graphene portion being represented by the resistor R_{g} having a variable resistance. The current then passes through the “drain” electrode, represented as a resistor R_{d} having a fixed resistance. The voltage difference between the “source” electrode and the “drain” electrode is the value of the current source multiplied by the total resistance of Rₛ+R_{g}+R_{d}. This voltage difference is detectable and useful in determining whether contact/bonding of the graphene layer with a chemical agent or biological agent has occurred, as described above.

FIG. 4B illustrates details of circuitry 400B including a voltage source according to an illustrative embodiment. The voltage source 410B may be implemented with, for example, a self-bias circuit, a voltage multiplier, a band gap reference, or a commercial, off-the-shelf voltage source.

As shown in FIG. 4B, the voltage source 410B supplies voltage to a “source” electrode, represented as a resistor Rₛ having a fixed resistance. The voltage passes through the portion of the graphene layer between the “source” electrode and the “drain” electrode, the graphene portion being represented by the resistor R_{g} having a variable resistance. The voltage then passes through the “drain” electrode, represented as a resistor R_{d} having a fixed resistance. The current difference between the “source” electrode and the “drain” electrode is the value of the voltage source divided by the total resistance of Rₛ+R_{g}+R_{d}. This current difference is detectable and useful in determining whether contact/bonding of the graphene layer with a chemical agent or biological agent has occurred, as described above.

The current and voltage sources shown in FIGS. 4A and 4B, respectively, can be connected to the underlying detection circuitry in the CMOS detection layer 130 as an interconnect or as an input to any of the active components, such as inputs to the components.

As indicated above, contact or bonding of different chemical agents and biological agents with the graphene layer 120 will create different charges, thus creating different changes in resistance of the graphene layer 120. Thus, each particular biological agent or chemical agent is associated with a corresponding particular resistance change or response.

Examples of resistance responses are illustrated in FIGS. 5A and 5B. FIG. 5A is a plot 500A showing a change in resistance of graphene upon contact or bonding with a biological or chemical agent. An example of a plot 500B of a normalized resistance of graphene over time is shown in FIG. 5B.

Based on a resistance response, such as that shown in FIG. 5B, a determination can easily be made as to what biological agent or chemical agent is present in the environment in which the detection device is located. Although not described here in detail, it should be appreciated that contact/bonding of each biological agent and chemical agent with graphene will also cause a corresponding voltage and current change. Thus, each biological agent and chemical agent also has an associated voltage response and current response.

Techniques for determining the presence of a biological agent or chemical agent based on a changed resistance of graphene vary depending on whether the graphene is functionalized or not functionalized.

If the graphene is not functionalized to bond with a particular agent, the agent that contacts the graphene can be determined by calibrating measured current or voltage differences caused by contact of the graphene with different agents in advance. For example, one specific chemical agent may cause a 1.6 Volt (V) change between electrodes, while another agent may cause a 1.7 V change. With the responses for various agents known in advance, the measured voltage or current change can be correlated with known responses to determine which agent has come in contact with the graphene.

Functionalization of the graphene allows for measured responses, because the functionalized graphene will only be affected by a specified chemical or biological agent.

It should be appreciated that, whether or not the graphene is functionalized, the detection device may need to be calibrated for different environments as the change in the resistance in the graphene due to contact/bonding of an agent may vary between different environments. That is, the device may need to be calibrated for various environmental factors including: temperatures, humidity levels, salinity, etc.

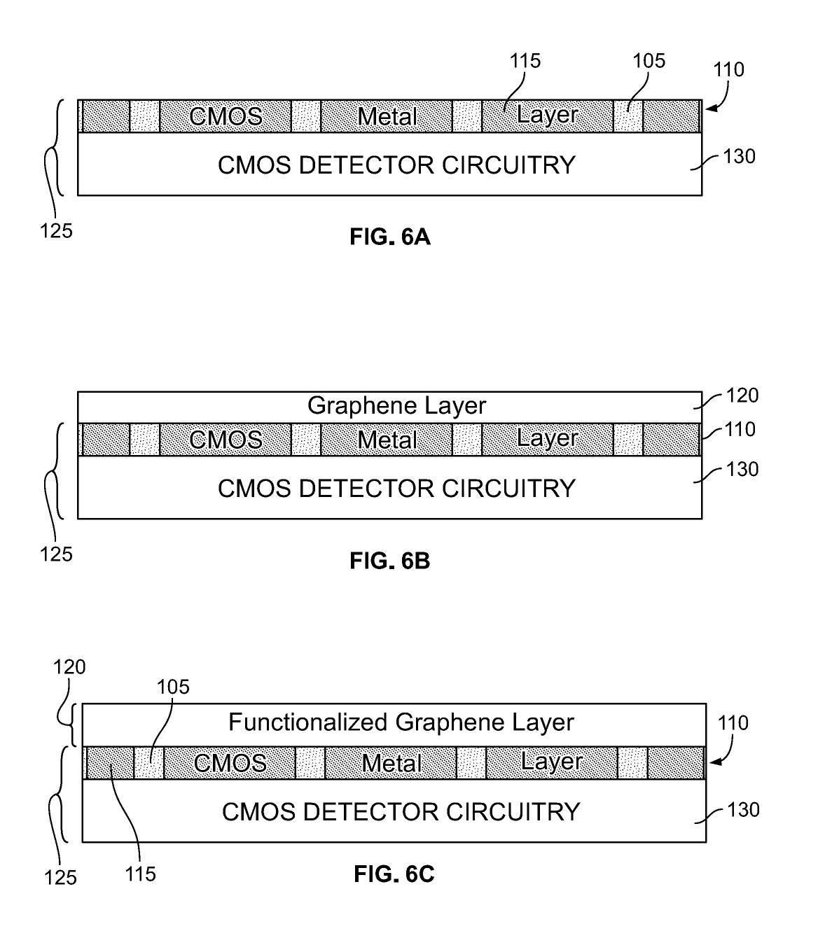

Having described how the detection device works, a description of how the detection device is fabricated is provided below. FIGS. 6A, 6B and 6C illustrate stages in a process for fabricating a graphene covered detection device according to an illustrative embodiment.

Referring to FIG. 6A, in a first stage, a metal CMOS layer 110 including electrodes 105 separated by insulating material 115 is applied to a CMOS detection layer 130 including bulk material and detection circuitry, forming a CMOS layer 125.

As shown in FIG. 6B, in a second stage, a graphene layer 120 is applied to the CMOS metal layer 110, such that it covers both the top surfaces of the electrodes 105 and the insulating material 115.

Although not shown in FIG. 6B, it should be appreciated that, before being applied to the CMOS layer 110, the graphene may be grown on a metal surface, such as copper. The graphene may be grown via any suitable method, such as chemical vapor deposition. The graphene may then be transferred to the CMOS metal layer 110 via, for example, a stamp-and-stick or dry/wet etching method.

It should be appreciated that the process may stop here, in the case in which only non-functionalized graphene is used in the detection device.

FIG. 6C illustrates a third stage in the fabrication process in the case in which functionalized graphene is used. In the third stage, the graphene layer 120 is functionalized. The graphene layer 120 may be functionalized for covalent bonding or non-covalent bonding with a particular bioagent or chemical agent. Examples of compounds that may be used for functionalization include ammonia, amino acids, ionic liquids, polymer/epoxy, sugars, salts, etc. The graphene may be functionalized with these or other compounds by, for example, dip coating, spray coating, spin coating, evaporating, or a variety of other deposition techniques.

Although functionalization of the graphene layer is shown in FIG. 6C as a third stage in the fabrication process, after the graphene layer is applied to the CMOS metal layer 110, it should be appreciated that the graphene layer may be functionalized before being applied to the CMOS metal layer 110.

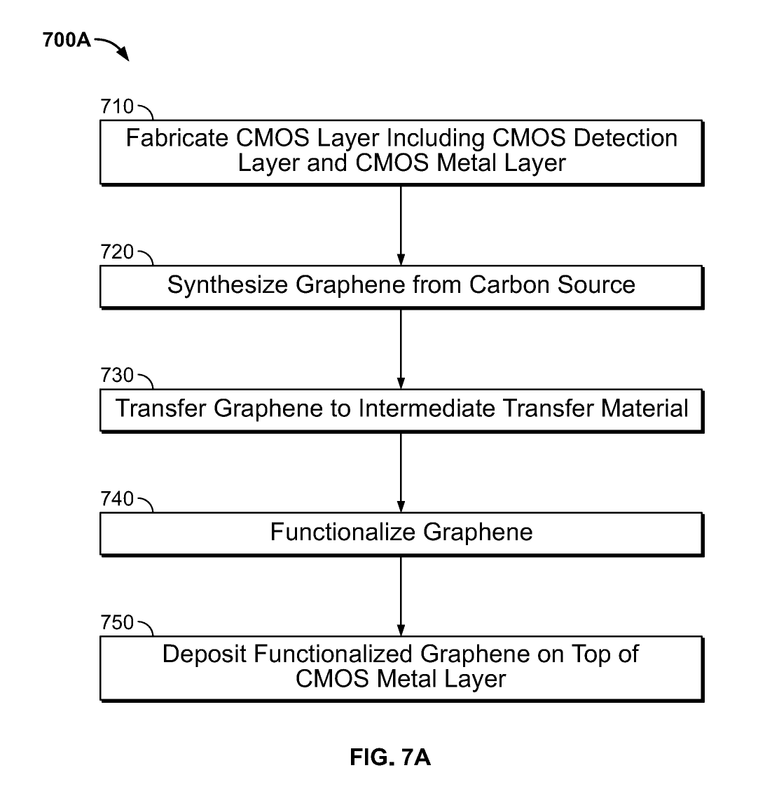

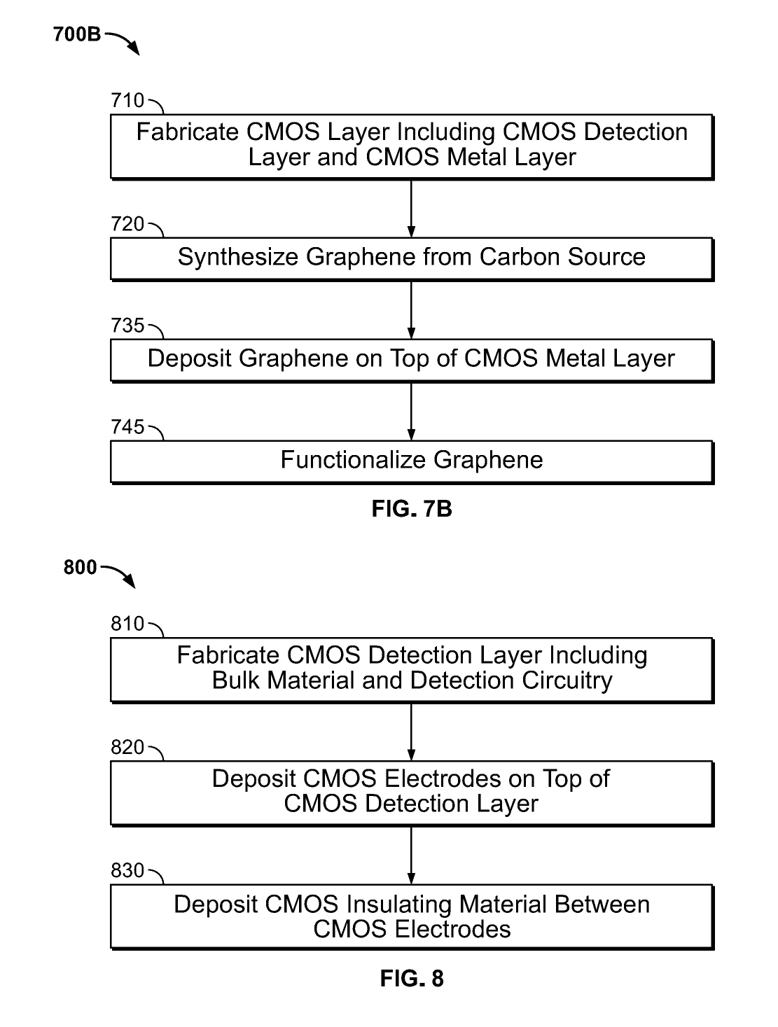

FIG. 7A is a flow chart illustrating the steps involved in a process for fabricating a functionalized graphene covered detection device according to an illustrative embodiment. The process 700A begins at step 710 at which a CMOS layer including a CMOS metal layer, such as the CMOS metal layer 110 shown in FIG. 1, and a CMOS detection layer, such as the CMOS detection layer 130 shown in FIG. 1, are fabricated. This step is described in more detail with reference to FIG. 8.

In FIG. 7A, at step 720, graphene is synthesized from a carbon source using, for example, chemical vapor deposition on a metal substrate, such as copper. At step 730, the graphene is transferred to an intermediate transfer material, which may include any suitable substrate. At step 740, the graphene is functionalized for bonding with a particular biological or chemical agent. At step 750, the functionalized graphene is deposited across a top surface of a CMOS metal layer, such as the CMOS metal layer 150 of FIG. 1, by transferring it from the intermediate transfer material to the surface of the CMOS metal layer.

FIG. 7B is a flow chart illustrating the steps involved in a process for fabricating a functionalized graphene covered detection device according to another illustrative embodiment. According to this embodiment, the graphene is functionalized after it is deposited on the CMOS metal layer.

Referring to FIG. 7B, the process 700B begins at step 710 at which a CMOS layer is fabricated, as described above with reference to FIG. 7A. At step 720, graphene is synthesized from a carbon source as described above with reference to FIG. 7A.

At step 735, instead of transferring the graphene to an intermediate transfer material as described above with reference to FIG. 7A, the graphene is deposited across a top surface of a CMOS metal layer, such as the CMOS metal layer 150 shown in FIG. 1. This may be performed by patterning the graphene on the top surface of the CMOS metal layer using, for example, dry/wet etching methods. At step 745 of FIG. 7B, the graphene is functionalized for bonding with a particular biological or chemical agent.

Whether the process illustrated in FIG. 7A or FIG. 7B is used, the result is a detection device including a CMOS layer covered with a graphene layer that is functionalized to cause a particular biological or chemical agent to bond with a surface of the graphene layer upon contact with the surface of the graphene layer. This causes a particular change in the resistance of the graphene that is detectable by circuitry in the underlying CMOS layer.

Referring now to the details for fabricating the CMOS layer (step 710 in FIGS. 7A and 7B), FIG. 8 is a flow chart illustrating the steps involved in a process for fabricating a CMOS layer including a metal layer and a detection layer according to an illustrative embodiment. As shown in FIG. 8, the process 800 begins at step 810 at which a CMOS detection layer, such as the CMOS detection layer 130 shown in FIG. 1, is fabricated. The CMOS detection layer includes bulk material and detection circuitry.

At step 820, CMOS electrodes, such as the CMOS electrodes 105 shown in FIG. 1, are deposited on top of the CMOS detection layer. At step 830, CMOS insulating material, such as the insulating material 115 shown in FIG. 1, is deposited between the electrodes.

It should be appreciated that the steps and order of steps described and illustrated are provided as examples. Fewer, additional, or alternative steps may also be involved and/or some steps may occur in a different order.

For example, although flowcharts shown in FIGS. 7A and 7B include a step for functionalizing the graphene layer, it should be appreciated that the graphene need not be functionalized before being deposited on the CMOS metal layer.

The detection device and methods for fabricating the device described above are optimal for rapid detection, sensitivity, selectivity, low false positives, and flexibility to adapt to respond to various biological and chemical agents in liquid or gaseous environments. The graphene based detection device could be easily integrated into an array of dynamic host platforms, such as unmanned aerial, ground or perhaps underwater vehicles. Fixed, unattended sensors could give critical warnings to forces at sea or in garrison. Because of the small size of the detection device and the low cost involved in fabricating it, large scale acquisition and fielding may be provided for sensing of the chemical and biological agents.

Preferred embodiments are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

What is claimed is:

1. A detection device for detecting a chemical or biological agent, comprising:
a metal layer including a plurality of electrodes;
a graphene layer covering a surface of the metal layer of the plurality of electrodes, wherein contact of a biological or chemical agent with a surface of the graphene layer causes a change in resistance of the graphene layer;
a detection layer connected to the plurality of electrodes, wherein the detection layer includes detection circuitry configured to detect a change in resistance as a function of a measured change in a current or voltage between adjacent electrodes in the plurality of electrodes.

2. The detection device of claim 1, wherein the detection circuitry is configured to measure the change in current or voltage by measuring a difference between the current or voltage at adjacent electrodes.

3. The detection device of claim 1, wherein the plurality of electrodes are arranged in an array.

4. The detection device of claim 3, wherein the detection circuitry is configured to measure changes in current or voltage between pairs of adjacent electrodes in the array.

5. The detection device of claim 1, wherein the graphene layer is functionalized such that a particular biological or chemical agent bonds with the surface of the functionalized graphene layer upon contact with the surface of the functionalized graphene layer, causing the change in resistance of the graphene layer.

6. The detection device of claim 5, wherein biological or chemical agents that are different from the biological or chemical agents to which the graphene layer is functionalized to bond are repelled from the surface of the graphene layer.

7. The detection device of claim 1, wherein contact of a particular biological or chemical agent with the surface of the graphene layer causes a corresponding particular change in resistance of the graphene layer.

8. The detection device of claim 5, wherein bonding of a particular biological or chemical agent with the surface of the graphene layer causes a corresponding particular change in resistance of the graphene layer.

9. The detection device of claim 1, wherein the detection device detects the presence and concentration of the chemical or biological agent in a liquid or gaseous environment.

10. A detection device for detecting a particular chemical or biological agent, comprising:
a metal layer including a plurality of electrodes arranged in an array;
a graphene layer covering a surface of the metal layer of the plurality of electrodes, wherein the graphene layer is functionalized such that the particular biological or chemical agent bonds with the surface of the graphene layer upon contact with the surface of the graphene layer, causing a change in resistance of the graphene layer; and
a detection layer connected to the plurality of electrodes, wherein the detection layer includes detection circuitry configured to detect the change in resistance as a function of measured changes in current or voltage between pairs of adjacent electrodes in the array of the plurality of electrodes.

11. The detection device of claim 10, wherein the detection circuitry is configured to measure the changes in current or voltage by measuring differences between the current or voltage at adjacent electrodes in the array of the plurality of electrodes.

12. The detection device of claim 10, further comprising a current source supplying a known current to the detection circuitry.

13. The detection device of claim 12, wherein the detection circuitry measures a change in the voltage between each pair of the adjacent electrodes, and the change in resistance is detected as a function of the known current and the measured voltage change.

14. The detection device of claim 10, further comprising a voltage source supplying a known voltage value to the detection circuitry.

15. The detection device of claim 14, wherein the detection circuitry measures a change in current between each pair of the adjacent electrodes in the plurality of electrodes, and the change in resistance is detected as a function of the known voltage and the measured current change.

16. The detection device of claim 10, wherein the detection circuitry includes a plurality of differential amplifiers.

17. The detection device of claim 10, wherein the detection circuitry includes one differential amplifier for each pair of adjacent electrodes within the array of the plurality of electrodes.

18. The detection device of claim 10, wherein the plurality of electrodes are complementary metal oxide semiconductor (CMOS) electrodes.

19. A method of fabricating a detection device for detecting a particular biological or chemical agent, comprising:
depositing a complementary metal oxide semiconductor (CMOS) metal layer including an array of CMOS electrodes separated by insulating material on a top surface of a CMOS detection layer, the CMOS detection layer including bulk material and CMOS detection circuitry;
depositing a graphene layer across a top surface of the CMOS metal layer, such that the CMOS electrodes are in contact with the graphene layer and the CMOS detection layer; and
functionalizing the graphene layer to cause the particular biological or chemical agent to bond with a surface of the graphene layer upon contact, wherein bonding of the particular biological or chemical agent causes a change in a resistance of the graphene layer.

20. The method of claim 19, wherein the change in resistance of the graphene layer is detectable by the CMOS detection circuitry as a function of changes in voltage or current between adjacent CMOS electrodes of the array of CMOS electrodes.
